(19) United States
(12) Patent Application Publication
(10) Pub. No.: US 2007/0277998 A1
(43) Pub. Date: Dec. 6, 2007

(54) Printed wiring board, its manufacturing method, and electronic equipment

(75) Inventors: Daigo Suzuki, Yokohama-shi (JP); Jun Karasawa, Tokyo (JP); Sadahiro Tamai, Ome-shi (JP)

Correspondence Address: PILLSBURY WINTHROP SHAW PITTMAN, LLP;Eric S. Cherry - Docketing Supervisor, P.O. BOX 10500, MCLEAN, VA, 22102, US

(73) Assignee: KABUSHIKI KAISHA TOSHIBA, Tokyo (JP)

(21) Appl. No.: 11/806,203

(22) Filed: May 30, 2007

(30) Foreign Application Priority Data
May 30, 2006 (JP) 2006-150032

(51) Int. Cl. H05K 1/03

(52) U.S. Cl. 174/255

(57) ABSTRACT

According to one embodiment, a printed wiring board includes a first layer, a flexible sheet member disposed at a part on a surface of the first layer, and a second layer which is disposed on the first layer and the flexible sheet member, a part of the second layer which corresponds to the flexible sheet member including an opening region.

### CROSS-REFERENCE TO RELATED APPLICATIONS

This application is based upon and claims the benefit of priority from Japanese Patent Application No. 2006-150032, filed May 30, 2006, the entire contents of which are incorporated herein by reference.

### BACKGROUND

1. Field

One embodiment of the invention relates to a printed wiring board which gives a bending property at a part thereof, its manufacturing method, and electronic equipment.

2. Description of the Related Art

As to a technique which gives a bending property at a part of a rigid printed wiring board, a technique, which forms a bent part in a part of a region among a plurality of rigid substrates by interposing an insulating layer made of a flexible insulating material among the plurality of rigid substrates, and by integrating the plurality of rigid substrates through the insulating layer, has been proposed (Jpn. Pat. Appln. KOKAI Publication No. 2001-036246). The technique may be achieved by using an insulating material of a polyimide group which is used for a base material of a flexible printed circuit (FPC) as the flexible insulating material.

However, a polyimide base material having a high water absorption coefficient, it tends to cause a shape change due to moisture absorbency and to cause an electrical property change, and in mounting components, it needs to be applied baking processing before mounting the, and also it has a problem of productivity because of a high cost of its material. Therefore, making a rigid substrate which has a bending property by cutting and thinning a part to be given the bending property thereof is a possible approach. For example, it becomes possible for a printed wiring board in which an A layer and a B layer are stacked to form a bent part in a cut region by cutting a part of the A layer up to a joint face of the B layer. However, such a case poses the problem that a cut face becomes uneven, and stress in bending concentrates to the thinned part to break the wiring board. Such a case also produces the problem that it is required for a fine cutting process with high precision to cut a part of the A layer up to a position reaching the joint face of the B layer, and that it takes a long time for the cutting off process.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary side cross-sectional view depicting a structure of a printed wiring board a part of which is formed as a bent part regarding an embodiment of the present invention;

FIG. 2 is an exemplary side cross-sectional view depicting a bent structure example of a printed wiring board regarding the embodiment;

FIG. 3 is an exemplary side cross-sectional view depicting a manufacturing process of the printed wiring board regarding the embodiment;

FIG. 4 is an exemplary side cross-sectional view depicting a flexible sheet member of the printed wiring board of the embodiment;

FIG. 5 is an exemplary side cross-sectional view depicting a flexible sheet member of the printed wiring board of the embodiment;

FIG. 6 is an exemplary side cross-sectional view depicting a manufacturing process of the printed wiring board regarding the embodiment;

FIG. 7 is an exemplary side cross-sectional view depicting a manufacturing process of the printed wiring board regarding the embodiment;

FIG. 8 is an exemplary side cross-sectional view depicting a manufacturing process of the printed wiring board regarding the embodiment; and

FIG. 9 is a side cross-sectional view depicting a structure of electronic equipment regarding the present invention.

### DETAILED DESCRIPTION

Various embodiments according to the invention will be described hereinafter with reference to the accompanying drawings. In general, according to one embodiment of the invention, a printed wiring board includes a first layer, a flexible sheet member disposed at a part on a surface of the first layer, and a second layer which is disposed on the first layer and the flexible sheet member, a part of the second layer which corresponds to the flexible sheet member including an opening region.

The present invention provides a printed wiring board which gives a partial bending property by sandwiching a flexible sheet member such as a silver shield member or a solder resist having a bending property between an A layer and a B layer, and by removing the A layer and by thinning a part of the B layer.

A printed wiring board structure with such a structure may form a bent area in which a cut face becomes flat, and may provide a printed wiring board which avoid break in bending to improve a yield ratio and has a bending property at a part thereof.

Hereinafter, embodiments of the invention will be described with reference to the drawings.

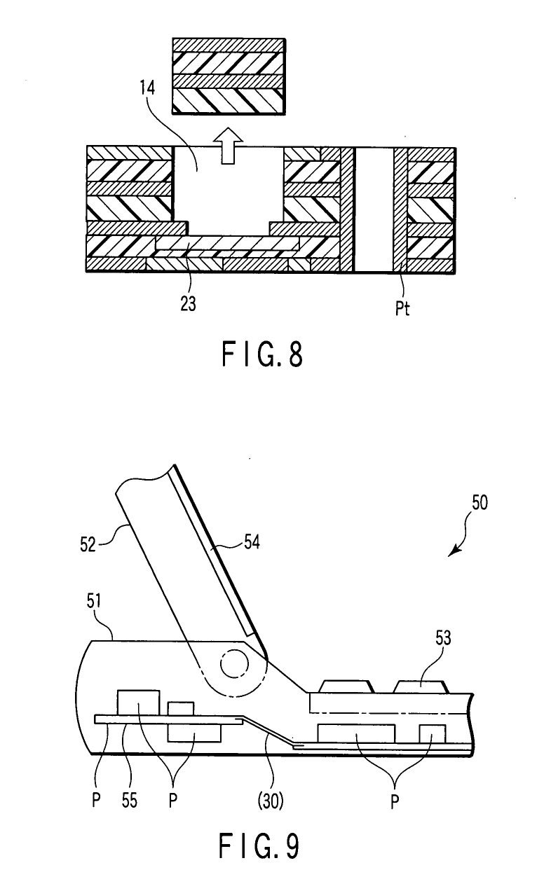

Referring now to FIG. 1 to FIG. 8, a printed wiring board regarding the embodiment of the invention will be set forth together with manufacturing processes of the printed wiring board.

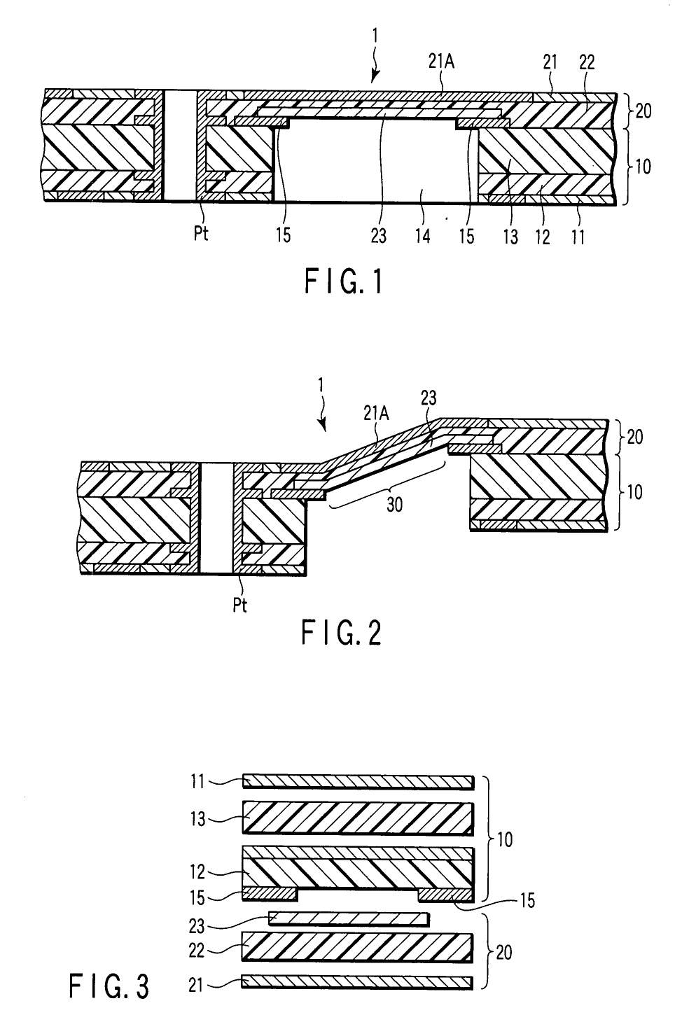

FIG. 1 to FIG. 8 indicate manufacturing processes of the printed wiring board according to the embodiment of the invention. FIG. 1 illustrates a structure of the printed wiring board according to the embodiment of the invention that is deliverables manufactured through the processes from FIG. 3 to FIG. 8, and FIG. 2 illustrates an example of the printed wiring board which is applied a bending process.

A printed wiring board 1 according to a embodiment of the invention has, as shown in FIG. 1 and FIG. 2, a stacked first layer 10 and a second layer 20.

In the wiring board 1 depicted in FIG. 1, the first layer 10 is structured to have an insulating layer 12 formed of a core material and an insulating layer 13 formed of a prepreg material. Conductive layers are formed on both surfaces of the insulating layer 12 which is formed of the core material. Conductive patterns 15 contacting with opposed end faces of a flexible sheet member 23 are formed by means of etching in a conductive layer joining to the second layer 20. A conductive layer 11 is formed on one surface of the insulating layer 13 formed of the prepreg material.

The second layer 20 includes an insulating layer 22 formed of the prepreg material. Conductive layers are formed on both surfaces of the insulating layer 22. FIG. 1 shows the structure by which a conductive pattern 21A is formed so as to striding across a bent area 30 in a conductive layer 21 formed on a side of an outer most layer.

A though plug Pt to circuit-connect the first layer 10 to the second layer 20 is formed in the first and the second layers 10 and 20.

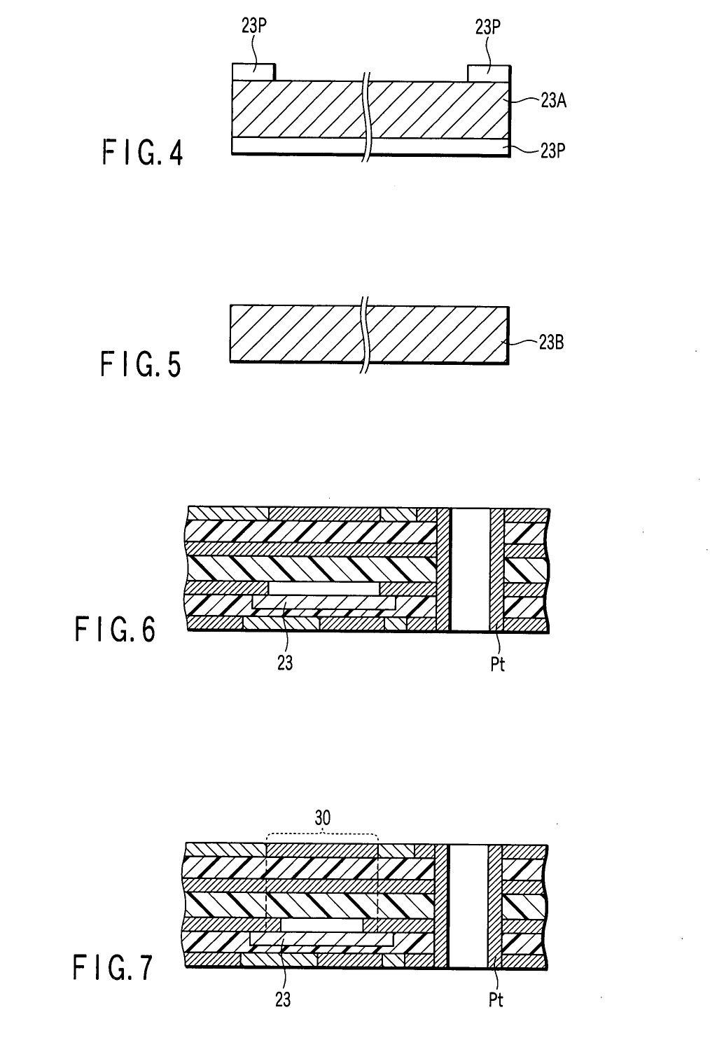

The flexible sheet member 23 is disposed between the stacked first and second layers 10 and 20. The flexible sheet member 23 is disposed on the side of the second layer 20. The flexible sheet member 23 is composed of a silver shield material 23A shown in FIG. 4, or a solder resist having a bending property shown in FIG. 5.

When the silver shield material 23A is used for the flexible sheet member 23, as depicted in FIG. 4, conductive adhesives 23Ps are applied to a surface overlapping on the conductive patterns 15, and to a surface overlapping on the insulating layer 22 of the second layer 20, respectively, and the silver shield material 23A and the insulating layer 22, and the silver shield material 23A and the conductive patterns 15 are bonded, respectively.

The conductive patterns 15 individually contacting with one and the other end of the flexible sheet member 23 disposed on the face contacting with the first layer 10 of the second layer 20 in the conductive layer contacted with the second layer 20 of the first layer 10. The conductive patterns 15 are formed through etching. Thereby, in a state in which the first and the second layers 10 and 20 are laminated with each other, an interval corresponding to the thickness of the patterns 15 is formed between the patterns 15 on the joint face of the first and the second layers 10 and 20.

The opposed ends of the flexible sheet member 23 are sandwiched between the insulating layer 22 formed of the prepreg material disposed in the second layer 20 and the conductive patterns 15 disposed in the first layer 10.

An opening part 14 which is made by cutting the part corresponding to the flexible sheet member 23 is disposed in the first layer 10. The opening part 14 is formed through a cutting process by a router, or through a laser process. The opening part 14 is formed by cutting reaching the conductive layer which has formed the conductive patterns 15 in the first layer 10. Therefore, the opening part 14 communicates with the interval formed between the conductive patterns 15, and a part of the conductive patterns 15, and the part other than the opposed ends of the flexible sheet member 23 are exposed to the opening part 14, respectively. The region of the part exposed by the opening part 14 becomes a bent area. Opposed ends of the bent area are reinforced in a bending direction by means of the conductive patterns 15 to improve the bending durability.

FIG. 2 illustrates an example of the bending of the printed wiring board 1 forming the bent area shown in FIG. 1. The example of the bending shown in FIG. 2 depicts an example in which a printed wiring board with the first and the second layer 10 and 20 stacked thereon structures a printed wiring board having a part of a difference in level which has been made by each bending both ends of the bent area 30 formed by the opening part 14.

In such a printed wiring board structure regarding the embodiment of the invention, the part exposed to the opening part 14 being flat and it resulting in the distribution of the stress in bending into a wide range, the printed wiring board structure avoids the breakage in bending and improves the yield ratio. Further, in the cutting process of the opening part 14, the wiring board structure having a stacked structure communicating the opening part 14 with the interval between the conductive patterns 15, it does not need the fine cutting process with high precision taking a long time, and it may form the opening part 14 with ease and in a short time.

Hereinafter, the manufacturing processes of the printed wiring board 1 regarding the aforementioned embodiment will be described with reference to FIG. 3 to FIG. 8, and FIG. 1 and FIG. 2.

As shown in FIG. 3, the manufacturing process interposes the flexible sheet member 23 between the conductive patterns 15 formed in the first layer 10 to be the printed wiring board material and the second layer 20. The silver shield material 23A depicted in FIG. 4, or the solder resist having bending property 23B is used for the flexible sheet member 23. The thickness of the silver shield material 23A is about 32 μm. The thickness of the solder resist 23B is around 15 μm. In the case of the use of the silver shield material 23A, as shown in FIG. 4, the manufacturing process applies the conductive adhesives 23Ps onto the face of the first layer 10 overlapping on the conductive patterns 15, and the face of the second layer 20 overlapping on the insulating layer 22, respectively, and bonds the silver shield material 23A to the insulating layer 22, and the silver shield material 23A to the conductive patterns 15, respectively. In the case of the use of the solder resist 23B, the manufacturing process applies an adhesive to a resist base material to similarly bond them.

As depicted in FIG. 6, the manufacturing process forms the printed wiring board in accordance with pattern design, such as a through plug Pt and a solder resist on a pattern face.

As shown in FIG. 7, a cutting process to form the bent area 30 is performed. The cutting process forms the opening part 14, reaching the conductive layer with the conductive patterns 15, 15 in the first layer formed there in, in the region corresponding to the flexible sheet member 23 in the first layer 10 through the cutting process by the router, or through the laser process. The cutting process communicates the opening part 14 with the interval formed between the conductive patterns 15, and exposes the parts of the conductive patterns 15, and the part except the opposed ends of the flexible sheet member 23. The printed wiring board 1 having a stacked structure by which the opening part 14 communicates with the interval formed between the conductive patterns 15, the manufacturing process does not need the fine process with high precision to cutting the opening part 14, and also may form the opening part 14 in a short time.

FIG. 1 shows the printed wiring board structure which forms the bent area by means of the opening part 14 and has the bent part at a part thereof. The printed wiring board structure shown in FIG. 1 becomes a bent reinforcing structure which reinforces the opposed ends of the bent area exposed by the opening part 14 in a bent direction, and has high bending durability.

A fourth process depicted in FIG. 2 bending-processes the printed wiring board having a bent part at a part thereof to an objected shape. For example, as shown in FIG. 2, the printed wiring board formed of the stacked first layer 10 and the second layer 20 constitutes the printed wiring board 1 in which the part of a difference in level by bending the opposed ends of the bent area 30 formed by the opening part 14 at the same angle, respectively.

As given above, the embodiment of the invention provides a printed wiring board which has a partial bent part through the cutting process, and is excellent in yield ration. Since the manufacturing process does not need the fine cutting process and may form the bent area with ease and in a short time, the productivity thereof is improved. An expensive material, such as a polyimide insulating material not being needed as for the base material, a printed wiring board partially having bending performance may be provided at a low cost.

FIG. 9 illustrates a structure of electronic equipment with the printed wiring board having the bending property at a part thereof mounted thereon. Here, FIG. 9 depicts an example in which the printed wiring board manufactured through the forgoing embodiment is applied to small-sized electric equipment such as a portable computer.

In FIG. 9, a display unit housing 52 is provided so as to freely rotate via a hinge mechanism for a main body 51 of a portable computer 50. The main body 51 is provided with operation units, such as pointing devices, and a key board 53. The display unit housing 52 is provided with a display device 54, such as an LCD.

The main body 51 is provided with a printed circuit board (mother board) 55 with a variety of control circuit elements P to control the operation units, such as the pointing devices and keyboard 53, and a display device 54 installed therein. The printed circuit board 55 is achieved in use of the printed wiring board 1 which is manufactured in the embodiment shown in FIG. 2, and has the bending property at a part thereof (with the bent area 30 partially formed there in).

The printed wiring board used for the printed circuit board 55 has the bent area 30 which is bent in accordance with the mounting space of a substrate housing part of the main body 51 and is mounted in the main body 51. The printed circuit board 55 having the bent area at a part thereof is applicable to both cases in which the circuit board 55 is bent in advance in accordance with the mounting space of the substrate housing unit before mounting it on the main body 51, and in which the circuit board 55 is bent in a mounting process in mounting it on the main body 51, respectively. In the substrate structure by which a board face of a substrate is bent in, for instance, a heating process, it is possible, in mounting the substrate, to absorb the stress due to the bending by means of the bent part formed at a part thereof.

Using the printed circuit board 55 having the bent part at a part thereof may provide electronic equipment which effectively utilizes the substrate mounting space in the main body 51, and intends further miniaturizing. Applying the printed wiring board with high yield ratio may provide inexpensive electronic equipment. Employing a rigid printed wiring board using a glass epoxy material with a structure differing from an FPC structure allows providing electric equipment stable in electricity.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A printed wiring board comprising:
a first layer;
a flexible sheet member disposed at a part on a surface of the first layer; and
a second layer which is disposed on the first layer and the flexible sheet member, a part of the second layer which corresponds to the flexible sheet member including an opening region.

2. The board according to claim 1, wherein at least a part of the flexible sheet member is exposed from the opening region.

3. The printed wiring board according to claim 1, wherein the flexible sheet member is a silver shield member.

4. The printed wiring board according to claim 1, wherein the flexible sheet member is a solder resist having a bending property.

5. The printed wiring board according to claim 1, wherein the second layer includes a plurality of conductive layers, conductive patterns overlapping on end parts of the flexible sheet member are formed on both sides of the opening region in a conductive layer adjacent to the flexible sheet member among the plurality of conductive layers.

6. The printed wiring board according to claim 1, wherein the first layer includes a plurality of conductive layers, and a wiring pattern striding across the bending part at least one conductive layer.

7. The printed wiring board according to claim 1, wherein the flexible sheet member is a silver shield material, the second layer includes a conductive pattern overlapping on end parts of the flexible sheet member on both sides of the opening region, and the conductive pattern disposed in the silver shield material and the second layer, and the silver shield material and the first layer are bonded with conductive adhesives, respectively.

8. The printed wiring board according to claim 7, wherein the second layer is formed by layering a prepreg material and a core material, and the conductive pattern is formed on the core material by etching.

9. A bending process method of a printed wiring board comprising:
stacking a first layer, a flexible sheet member, and a second layer, the flexible sheet member disposing at a part between the first layer and the second layer; and
cutting at least a part of the second layer of a part corresponding to the flexible sheet member.

10. The bending process method according to claim 9, wherein the flexible sheet member is a silver shield material, or a solder resist having a bending property.

11. The bending process method according to claim 9, wherein the flexible sheet member is a silver shield member, and the second layer includes a conductive pattern overlapping on end parts of the flexible sheet member on both sides of the opening region, and the method further comprising:
bonding the silver shield material and the conductive pattern disposed in the second layer, and the silver shield material and the first layer with conductive adhesives, respectively.

12. Electronic equipment equipped with a circuit board of which the part is bent in a housing body, wherein
the circuit board is composed of a first layer; a flexible sheet member disposed at a part on a surface of the first layer; and a second layer which is disposed on the first layer and the flexible sheet member, a part of the second layer which corresponds to the flexible sheet member including an opening region.

13. The Electronic equipment according to claim 12, wherein the circuit board is mounted in the housing body by producing a difference in level.

14. The equipment according to claim 12, wherein the circuit board is bent by being mounted in the housing body.
